(19) United States
(12) Patent Application Publication
(10) Pub. No.: US 2016/0079207 A1
(43) Pub. Date: Mar. 17, 2016

(54) SEMICONDUCTOR DEVICE AND METHOD FOR MANUFACTURING SAME

(71) Applicant: PS4 Luxco S.a.r..L., Luxembourg (LU)

(72) Inventors: Masahiro Yamaguchi, Tokyo (JP); Toro Saga, Tokyo (JP); Koji Hosokawa, Tokyo (JP)

(21) Appl. No.: 14/785,922

(22) PCT Filed: Apr. 16, 2014
(86) PCT No.: PCT/JP2014/060794

§ 371 Date: Oct. 21, 2015

(30) Foreign Application Priority Data
Apr. 23, 2013 (JP) 2013-090677

(51) Int. Cl. H01L 25/065; H01L 23/00; H01L 21/3105; H01L 21/48; H01L 25/00; H01L 21/56; H01L 23/498; H01L 23/31

(52) U.S. Cl. CPC H01L 25/0657; H01L 23/49838; H01L 24/17; H01L 23/3107; H01L 21/4853; H01L 24/81; H01L 25/50; H01L 21/56; H01L 24/11; H01L 21/31053; H01L 2225/06517; H01L 2225/06572; H01L 2225/06548; H01L 2224/13025; H01L 2924/10161; H01L 2224/16227; H01L 2224/81191; H01L 2224/11334

(57) ABSTRACT

[Problem] To provide a semiconductor device suitable for use as an upper-side package of a semiconductor device having a PoP structure. [Solution] This invention is provided with a semiconductor chip (10) flip-chip mounted on one surface (32) of a wiring board (30), and a semiconductor chip (20) flip-chip mounted on the other surface (33) of the wiring board (30), the semiconductor chips (10, 20) being installed in directions that differ by 90°. It is thereby possible to prevent the layout of wiring patterns (41, 42) on the wiring board (30) from becoming locally congested and enhance the freedom of layout. In addition, when the semiconductor chips (10, 20) are mounted on the wiring board (30), the location at which the load concentrates can be held by a stage, thereby making it possible to prevent the wiring board from deforming.

### TECHNICAL FIELD

The present invention relates to a semiconductor device and to a method for manufacturing same, and in particular the present invention relates to a semiconductor device in which a semiconductor chip is flip-chip mounted on both surfaces of a wiring board, and to a method for manufacturing same.

### BACKGROUND

In recent years there have been proposals for semiconductor devices in which a plurality of semiconductor chips are flip-chip mounted on a rigid wiring board. For example, Patent Document 1 describes a semiconductor device of the type in which a semiconductor chip is flip-chip mounted on both surfaces of a wiring board. This makes it possible to achieve higher density packaging if the semiconductor chips are flip-chip mounted on both surfaces of the wiring board in this way.

### PATENT DOCUMENTS

Patent Document 1: JP 2006-210566 A

Patent Document 2: JP 2007-287906 A

Patent Document 3: JP 2010-103348 A

### SUMMARY OF THE INVENTION

### Problem to be Solved by the Invention

With the semiconductor device described in Patent Document 1, however, the semiconductor chip and an external terminal are disposed on the same plane (rear surface) of the wiring board, so the difference in height (“stand-off”) between the rear surface of the semiconductor chip and the tip end of the external terminal is very small. This leads to the problem of difficulty in mounting on the surface of a substrate which is uneven. The surface of a lower-side package of a semiconductor device having a Package-on-Package (PoP) structure corresponds to the surface of a substrate which is uneven, for example. It would therefore be difficult to use the semiconductor device described in Patent Document 1 as an upper-side package in a semiconductor device having a PoP structure.

In order to solve this kind of problem, a method in which conductive posts are made to project from a wiring board has been considered, as in the semiconductor device described in Patent Document 2. However, if conductive posts are made to project from a wiring board, the stand-off becomes excessive because of the structure of the lower-side package and the overall thickness may be increased more than necessary. Furthermore, the semiconductor device described in Patent Document 2 is not a device in which semiconductor chips are mounted on both surfaces of a wiring board or flip-chip mounting is performed, so it is unclear how to apply it to a semiconductor device of the type in which semiconductor chips are flip-chip mounted on both surfaces of a wiring board.

Furthermore, although Patent Document 3 does not relate to a semiconductor device in which a semiconductor chip is flip-chip mounted, that document describes a structure in which semiconductor chips are mounted on both surfaces of a wiring board and covered by a sealing resin, and the wiring board and an external terminal are connected by way of a through-hole conductor provided running through the sealing resin. When semiconductor chips are flip-chip mounted on a wiring board, however, a process is required in which the semiconductor chips are pressed against the wiring board while a load and ultrasound are applied, but the semiconductor device described in Patent Document 3 employs wire bonding, and therefore problems specific to flip-chip mounting, e.g. problems such as deformation of the wiring board caused by application of load and ultrasound, do not arise.

### Means for Solving the Problem

A semiconductor device according to the present invention is characterized in that it comprises: a wiring board having a plurality of first connection pads formed on a first surface, a plurality of second connection pads formed on a second surface, and a plurality of lands which are disposed on the second surface and are electrically connected to the first or second connection pads; a first semiconductor chip having a first surface defined by opposing first and second ends and opposing third and fourth ends, and a plurality of first bump electrodes which are disposed along the first and second ends on the first surface, said first semiconductor chip being mounted on the first surface of the wiring board in such a way that the plurality of first bump electrodes are connected to the plurality of first connection pads; a first sealing resin which is formed on the first surface of the wiring board in such a way as to cover the first semiconductor chip; a second semiconductor chip having a first surface defined by opposing first and second ends and opposing third and fourth ends, and a plurality of second bump electrodes which are disposed along the first and second ends on the first surface, said second semiconductor chip being mounted on the second surface of the wiring board in such a way that the plurality of second bump electrodes are connected to the plurality of second connection pads and in such a way that the first and second ends of the second semiconductor chip are disposed parallel to the third and fourth ends of the first semiconductor chip; a second sealing resin which is formed on the second surface of the wiring board in such a way as to cover the second semiconductor chip; a plurality of conductive posts which are provided running through the second sealing resin and are connected at a first end to each of the plurality of corresponding lands while a second end thereof is exposed from the second sealing resin; and a plurality of solder balls which are mounted at the second end of the plurality of conductive posts.

A method for manufacturing a semiconductor device according to the present invention is characterized in that it comprises the following steps: a step in which a plurality of first connection pads are formed on a first surface of a wiring board, and a plurality of second connection pads, a plurality of lands which are electrically connected to the first or second connection pads, and a plurality of conductive posts which are connected at a first end to each of the corresponding plurality of lands, are formed on a second surface of the wiring board; a step in which a first semiconductor chip having a first surface defined by opposing first and second ends and opposing third and fourth ends, and a plurality of first bump electrodes disposed along the first and second ends of the first surface is mounted on the first surface of the wiring board in such a way that the plurality of first bump electrodes are connected to the plurality of first connection pads; a step in which a second semiconductor chip having a first surface defined by opposing first and second ends and opposing third and fourth ends, and a plurality of second bump electrodes disposed along the first and second ends of the first surface is mounted on the second surface of the wiring board in such a way that the plurality of second bump electrodes are connected to the plurality of second connection pads and in such a way that the first and second ends of the second semiconductor chip are disposed parallel to the third and fourth ends of the first semiconductor chip; a step in which first and second sealing resins are formed on the first and second surfaces, respectively, of the wiring board in such a way as to cover the first and second semiconductor chips; a step in which the second sealing resin is ground in such a way that a second end of the plurality of conductive posts is exposed; and a step in which a plurality of solder balls are mounted at the second end of the plurality of conductive posts.

### Advantage of the Invention

According to the present invention, solder balls are mounted at a second end of conductive posts which run through sealing resin, and therefore it is possible to maintain adequate stand-off Moreover, the mounting directions of two semiconductor chips mounted on both surfaces of a wiring board are offset from each other by 90°, so there is no localized clustering in the layout of the wiring pattern on the wiring board and there is a greater degree of freedom in the layout. Moreover, the location where a load is concentrated when the semiconductor chips are mounted on the wiring board using a bonding tool is held by means of a stage, so deformation occurring in the wiring board can be prevented.

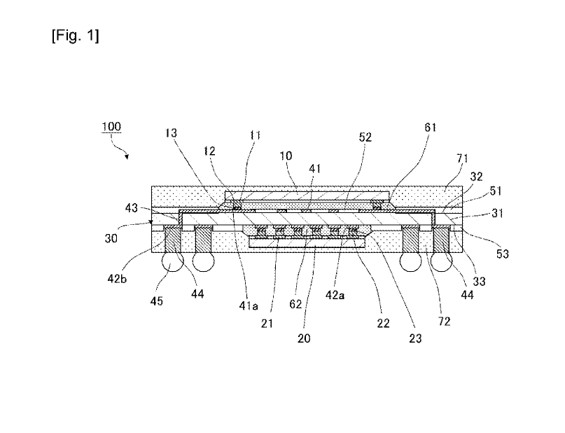

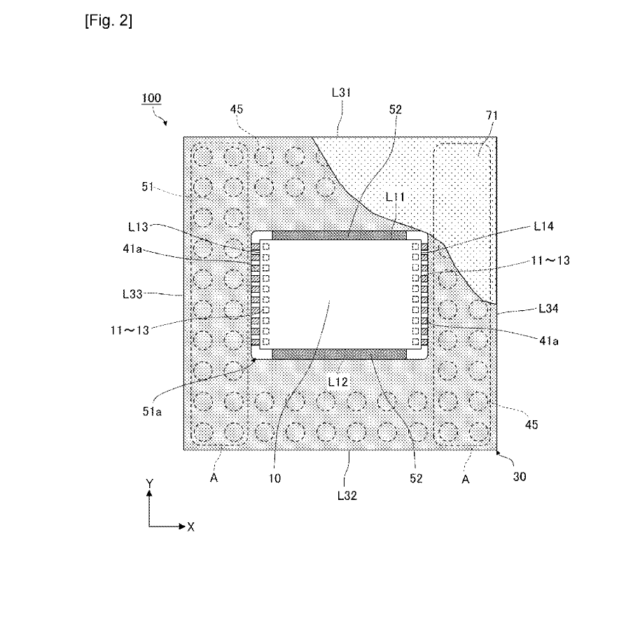

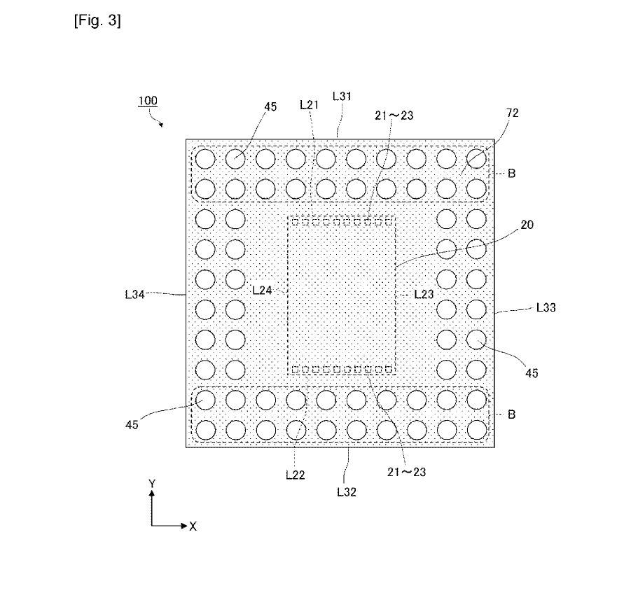

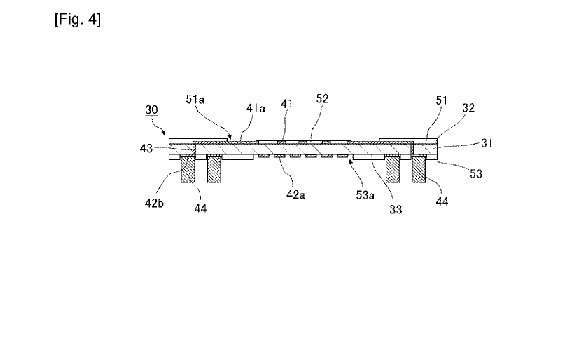

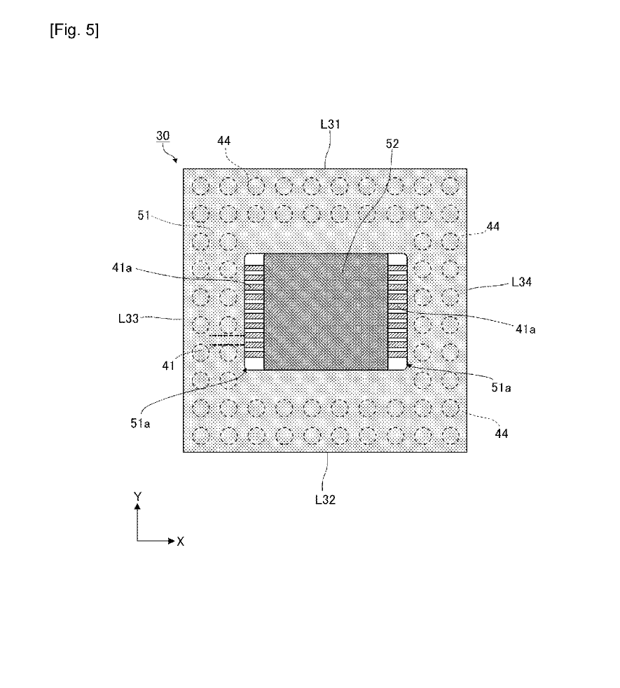

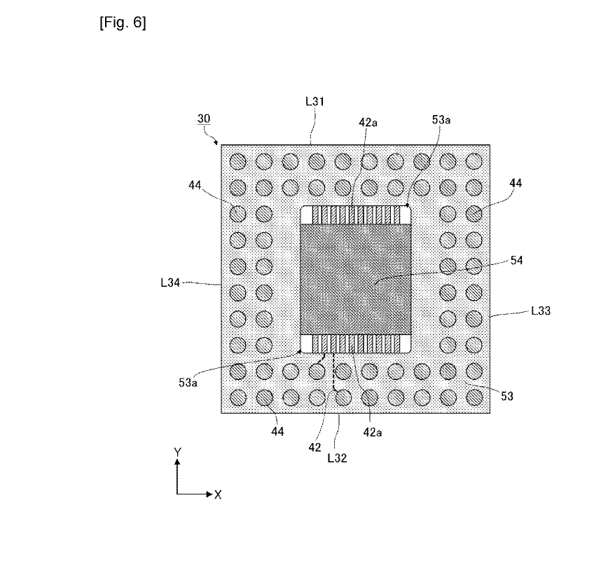

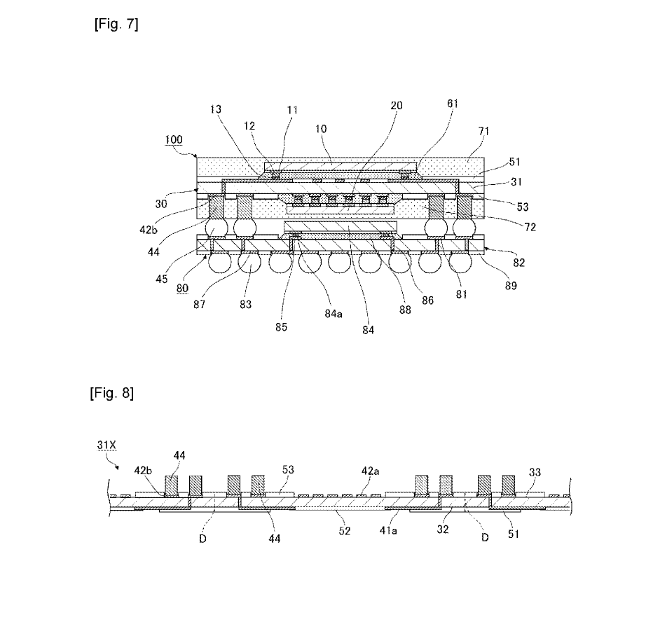

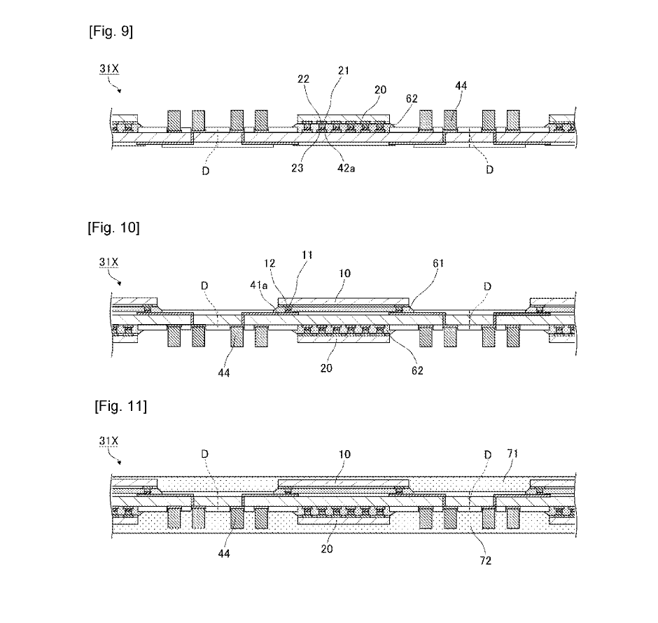

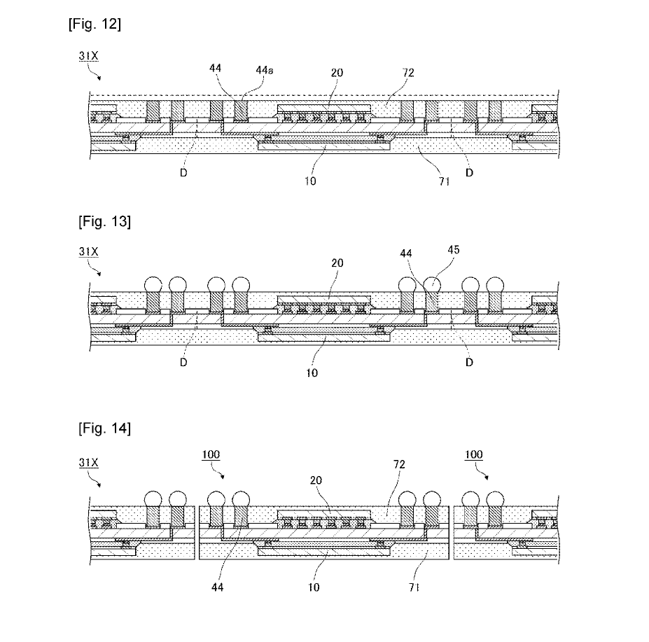

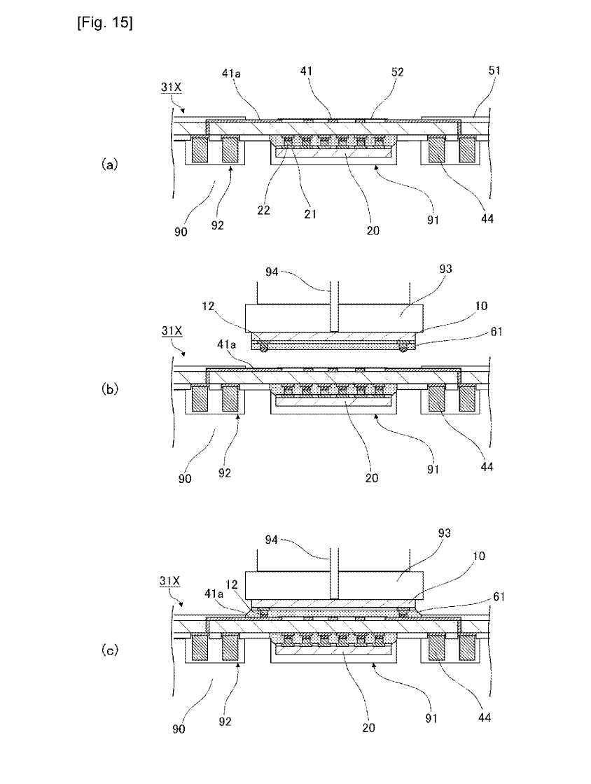

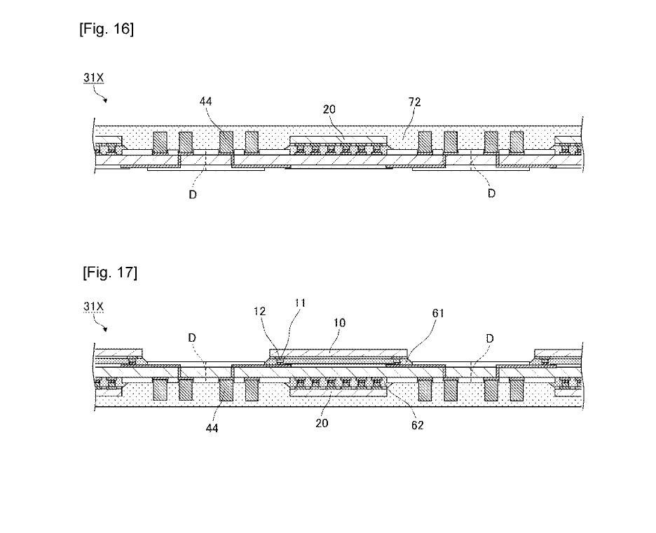

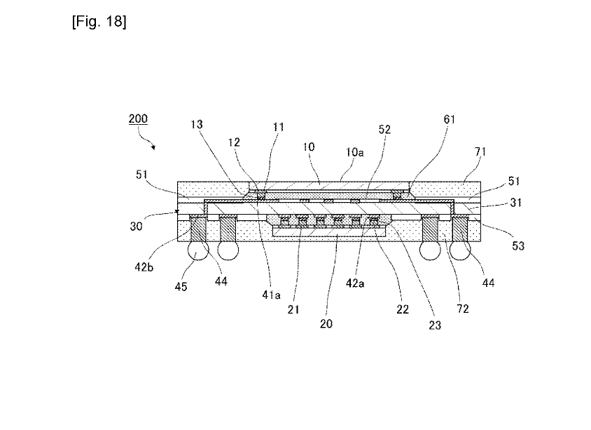

### BRIEF DESCRIPTION OF THE FIGURES

[FIG. 1] is a view in cross section showing the configuration of a semiconductor device 100 according to a first mode of embodiment of the present invention;

[FIG. 2] is a schematic plan view of the semiconductor device 100 seen from the upper surface direction;

[FIG. 3] is a schematic plan view of the semiconductor device 100 seen from the rear surface direction;

[FIG. 4] is a view in cross section showing a wiring board 30 removed from the semiconductor device 100;

[FIG. 5] is a schematic plan view of the wiring board 30 seen from the upper surface direction;

[FIG. 6] is a schematic plan view of the wiring board 30 seen from the rear surface direction;

[FIG. 7] is a view in cross section showing the configuration of a semiconductor device having a PoP structure employing the semiconductor device 100;

[FIG. 8] is a process diagram to illustrate a method for manufacturing the semiconductor device 100;

[FIG. 9] is a process diagram to illustrate the method for manufacturing the semiconductor device 100;

[FIG. 10] is a process diagram to illustrate the method for manufacturing the semiconductor device 100;

[FIG. 11] is a process diagram to illustrate the method for manufacturing the semiconductor device 100;

[FIG. 12] is a process diagram to illustrate the method for manufacturing the semiconductor device 100;

[FIG. 13] is a process diagram to illustrate the method for manufacturing the semiconductor device 100;

[FIG. 14] is a process diagram to illustrate the method for manufacturing the semiconductor device 100;

[FIG. 15] is a drawing to illustrate a method for flip-chip mounting a semiconductor chip 10 on a first surface 32 of an insulating substrate 31;

[FIG. 16] is a process diagram to illustrate a manufacturing method according to a variant example of the semiconductor device 100;

[FIG. 17] is a process diagram to illustrate a manufacturing method according to a variant example of the semiconductor device 100; and

[FIG. 18] is a view in cross section showing the configuration of a semiconductor device 200 according to a second mode of embodiment of the present invention.

### MODE OF EMBODIMENT OF THE INVENTION

Preferred modes of embodiment of the present invention will be described in detail below with reference to the appended drawings.

FIG. 1 is a view in cross section showing the configuration of a semiconductor device 100 according to a first mode of embodiment of the present invention, and FIG. 2 and FIG. 3 are schematic plan views of the semiconductor device 100 seen from the upper surface direction and the rear surface direction, respectively. Furthermore, FIG. 4 is a view in cross section showing a wiring board 30 removed from the semiconductor device 100, and FIG. 5 and FIG. 6 are schematic plan views of the wiring board 30 seen from the upper surface direction and the rear surface direction, respectively.

As shown in FIG. 1-FIG. 3, a semiconductor device 100 according to this mode of embodiment is provided with a wiring board 30, and two semiconductor chips 10, 20 which are flip-chip mounted on both surfaces thereof. In this mode of embodiment, the semiconductor chips 10, 20 are dynamic random access memory (DRAM) chips and have the same circuit configuration and the same pad arrangement, although this is not particularly limiting. However, the present invention is not limited to this and the semiconductor chips 10, 20 may equally be other types of memory chips such as flash memory chips, or one of the semiconductor chips 10, 20 may be a memory chip and the other may be a control chip for controlling the memory chip.

As shown in FIG. 2, the semiconductor chip 10 is rectangular in shape with long sides L11, L12 lying in the X-direction and short sides L13, L14 lying in the Y-direction, and a plurality of pad electrodes 11 are arranged in the Y-direction along both short sides L13, L14. The sides L11-L14 of the semiconductor chip 10 constitute ends defining a first surface of the semiconductor chip 10 and face sides L31-L34 of the wiring board 30. A plurality of first bump electrodes 12 projecting from the first surface of the semiconductor chip 10 are provided on the pad electrodes 11. The bump electrodes 12 are made of a metallic material such as copper and a solder layer 13 is formed at the tip end thereof.

As shown in FIG. 3, the semiconductor chip 20 is rectangular in shape with short sides L21, L22 lying in the X-direction and long sides L23, L24 lying in the Y-direction, and a plurality of pad electrodes 21 are arranged in the X-direction along both short sides L21, L22. The sides L21-L24 of the semiconductor chip 20 constitute ends defining a first surface of the semiconductor chip 20 and face the sides L31-L34 of the wiring board 30. A plurality of second bump electrodes 22 projecting from the first surface of the semiconductor chip 20 are provided on the pad electrodes 21. The bump electrodes 22 are made of a metallic material such as copper and a solder layer 23 is formed at the tip end thereof.

The semiconductor chips 10, 20 thus have an edge pad structure in which the bump electrodes 12, 22 are formed along the short sides thereof, and the semiconductor chips 10, 20 are mounted on the wiring board 30 rotated through 90° from each other. That is to say, the long sides L11, L12 of the semiconductor chip 10 and the short sides L21, L22 of the semiconductor chip 20 are disposed parallel to one another, while the short sides L13, L14 of the semiconductor chip 10 and the long sides L23, L24 of the semiconductor chip 20 are disposed parallel to one another. As a result, the bump electrodes 12 of the semiconductor chip 10 are located in a different region in plan view from the mounting position of the semiconductor chip 20, and the bump electrodes 22 of the semiconductor chip 20 are located in a different region in plan view from the mounting position of the semiconductor chip 10.

The base material of the wiring board 30 is a rigid insulating substrate 31 which is formed by impregnating a core material such as a glass cloth with an epoxy resin or the like; the semiconductor chip 10 is flip-chip mounted on a first surface 32 thereof, and the semiconductor chip 20 is flip-chip mounted on a second surface 33 thereof The thickness of the insulating substrate 31 may be set at around 90 μm, although there is no particular limitation. A plurality of wiring patterns 41 and first and second insulating films 51, 52 for covering same are provided on the first surface 32 of the insulating substrate 31. A plurality of wiring patterns 42 and third and fourth insulating films 53, 54 for covering same are likewise provided on the second surface 33 of the insulating substrate 31. It is possible to use what is known as a solder resist for the insulating films 51-54. The insulating film 52 is preferably thinner than the insulating film 51, and the insulating film 54 is likewise preferably thinner than the insulating film 53, although this is not particularly limiting.

As shown in FIG. 5, the wiring patterns 41 include a plurality of first connection pads 41a where a portion thereof is exposed from the insulating films 51, 52, and the bump electrodes 12 of the semiconductor chip 10 are joined to the connection pads 41a with the solder layer 13 interposed. The insulating film 51 is formed in an outer peripheral region of the first surface 32 of the insulating substrate 31, and an opening 51a in which the insulating film 51 is not formed is provided in a central region. The insulating film 52 is formed within this opening 51a in such a way that the connection pads 41a are exposed. As shown in FIG. 2, the semiconductor chip 10 is mounted within the opening 51a in such a way that the bump electrodes 12 are connected to the connection pads 41a.

The gap between the semiconductor chip 10 and the insulating film 52 is filled with an underfill material 61. Here, a space may be reliably maintained between the semiconductor chip 10 and the insulating film 52 provided that the insulating film 52 is thin, and it is possible to prevent connection defects etc. caused by interference between the semiconductor chip 10 and the insulating film 52. Furthermore, the first surface 32 of the insulating substrate 31 which is uneven due to the presence of the wiring patterns 41 is rendered planar by the insulating film 52, so it is also possible to ensure fluidity when the underfill material 61 is charged. In addition, the rigidity of the wiring board 30 is enhanced if the insulating film 51 is thicker than the insulating film 52, and this facilitates handling.

As shown in FIG. 6, the wiring patterns 42 likewise include a plurality of connection pads 42a where a portion thereof is exposed from the insulating films 53, 54, and the bump electrodes 22 of the semiconductor chip 20 are joined to the connection pads 42a with the solder layer 23 interposed. The insulating film 53 is formed in an outer peripheral region of the second surface 33 of the insulating substrate 31, and an opening 53a in which the insulating film 53 is not formed is provided in a central region. The insulating film 54 is formed within this opening 53a in such a way that the connection pads 42a are exposed. The semiconductor chip 20 is mounted within the opening 53a in such a way that the bump electrodes 22 are connected to the connection pads 42a.

The gap between the semiconductor chip 20 and the insulating film 54 is filled with an underfill material 62. Here, a space may be reliably maintained between the semiconductor chip 20 and the insulating film 54 provided that the insulating film 54 is thin, and it is possible to prevent connection defects etc. caused by interference between the semiconductor chip 20 and the insulating film 54. Furthermore, the second surface 33 of the insulating substrate 31 which is uneven due to the presence of the wiring patterns 42 is rendered planar by the insulating film 54, so it is also possible to ensure fluidity when the underfill material 62 is charged. In addition, the rigidity of the wiring board 30 is enhanced if the insulating film 53 is thicker than the insulating film 54, and this facilitates handling.

Furthermore, the first surface 32 of the insulating substrate 31 is sealed by means of a first sealing resin 71 in such a way that the rear surface and the side surfaces of the semiconductor chip 10 are covered. The second surface 33 of the insulating substrate 31 is likewise sealed by means of a second sealing resin 72 in such a way that the rear surface and the side surfaces of the semiconductor chip 20 are covered. The sealing resins 71, 72 comprise a heat-curable epoxy resin or the like, although this is not particularly limiting.

A plurality of lands 42b which are electrically connected to the connection pads 41a or 42a are further provided on the second surface 33 of the insulating substrate 31. The lands 42b constitute part of the wiring patterns 42 and comprise a portion which is exposed from the insulating film 53. The lands 42b and the connection pads 41a are connected by way of through-hole conductors 43 which are provided running through the insulating substrate 31. The lands 42b are arranged in two rows along the sides L31-L34 of the wiring board 30 in such a way as to surround the connection pads 42a, although this is not particularly limiting.

As shown in FIG. 1, a plurality of conductive posts 44 comprising copper or the like which are provided running through the sealing resin 72 are provided on the lands 42b. As a result, a first end of the conductive posts 44 is connected to a corresponding land 42b, while a second end of the conductive posts 44 is exposed from the sealing resin 72. Here, the second end of the conductive posts 44 forms the same plane as the surface of the sealing resin 72. A solder ball 45 constituting an external electrode is mounted at the second end of the conductive posts 44.

According to this configuration, the bump electrodes 12, 22 of the semiconductor chips 10, 20 are both electrically connected to the solder balls 45 by way of the conductive posts 44. The solder balls 45 constitute terminals for connecting the semiconductor device 100 according to this mode of embodiment to an external device; if the semiconductor device 100 according to this mode of embodiment is mounted directly on a motherboard or a module substrate etc., the solder balls 45 are connected to lands provided on the motherboard or module substrate. Furthermore, when a semiconductor device having a Package-on-Package (PoP) structure is constructed using the semiconductor device 100 according to this mode of embodiment, the solder balls 45 are connected to lands 81 provided on the upper surface of another package 80, as shown in FIG. 7.

The package 80 shown in FIG. 7 employs a rigid wiring board 82, the surface of which is covered by an insulating film 89 comprising a solder resist. A semiconductor chip 84 is flip-chip mounted on a first surface of the wiring board 82, and solder balls 83 are provided on a second surface of the wiring board 82. Furthermore, lands 81 are provided on the first surface of the wiring board 82, and the solder balls 45 of the semiconductor device 100 according to this mode of embodiment are connected to the lands 81.

Bump electrodes 84a of the semiconductor chip 84 are connected to connection pads 85, and are connected to the lands 81 by way of a wiring pattern (not depicted), while also being connected to the solder balls 83 by way of through-hole conductors 86 and lands 87. The gap between the semiconductor chip 84 and the wiring board 82 is filled with an underfill material 88.

In the semiconductor device having a PoP structure shown in FIG. 7, another semiconductor chip 84 etc. is provided on the surface of the package 80, so unevenness is present on the surface on which the semiconductor device 100 is to be mounted. When the semiconductor device 100 is mounted on this uneven surface, it is necessary to maintain a sufficient difference in height (“stand-off”) between the surface of the sealing resin 72 and the tip end of the solder balls 45, but with the semiconductor device 100 according to this mode of embodiment, the second end of the conductive posts 44 and the surface of the sealing resin 72 form the same plane and the solder balls 45 are provided at the second end of the conductive posts 44, so it is possible to ensure adequate stand-off As a result, it is possible to easily obtain a PoP structure such as that shown in FIG. 7.

Furthermore, there is no need to increase the size of the solder balls 45 in order to enlarge the stand-off, as in Patent Document 1, so it is also possible to arrange a large number of solder balls 45 at a narrow pitch. In addition, the conductive posts 44 are not made to project, as in Patent Document 2, so the stand-off is not excessive either.

Moreover, the semiconductor device 100 according to this mode of embodiment is such that the first surface 32 of the wiring board 30 is covered by the sealing resin 71 while the second surface 33 thereof is covered by the sealing resin 72, so the vertical structure seen from the wiring board 30 is substantially symmetrical. As a result, it is also possible to achieve an advantage in that the semiconductor device 100 is unlikely to warp due to changes in temperature.

In addition, in the present mode of embodiment, the semiconductor chips 10, 20 are mounted on the wiring board 30 with an offset of 90° from each other, so the bump electrodes 12 of the semiconductor chip 10 can be connected at a short distance from the solder balls 45 in the regions A shown in FIG. 2, and the bump electrodes 22 of the semiconductor chip 20 can be connected at a short distance from the solder balls 45 in the regions B shown in FIG. 3. As a result, the wiring distance for connecting the semiconductor chip 10 and the solder balls 45 and the wiring distance for connecting the semiconductor chip 20 and the solder balls 45 can be made substantially equal in length, and it is therefore possible to achieve high signal quality. Moreover, the wiring patterns are not concentrated at specific locations on the wiring board 30 so there is a greater degree of freedom in the layout and it is also possible to increase the manufacturing yield.

A method for manufacturing the semiconductor device 100 according to this mode of embodiment will be described next.

FIG. 8-FIG. 14 are process diagrams to illustrate the method for manufacturing the semiconductor device 100 according to this mode of embodiment.

As shown in FIG. 8, a base material 31X for the insulating substrate 31, in which the wiring patterns 41 and insulating films 51, 52 are provided on the first surface 32, and the wiring patterns 42 and the insulating film 53 (and also the insulating film 54 which is not depicted) are provided on the second surface 33, is first of all prepared. The reference symbol D applied to the base material 31X indicates a dicing line. As mentioned above, the insulating substrate 31 is a rigid substrate which is formed by impregnating a core material such as a glass cloth with an epoxy resin or the like, so it can be handled without the use of another supporting substrate. Here, an opening for exposing the connection pads 41a constituting a portion of the wiring patterns 41 is formed in the insulating films 51, 52, and an opening for exposing the lands 42b and connection pads 42a constituting a portion of the wiring patterns 42 is formed in the insulating films 53, 54.

A plurality of conductive posts 44 connected to the lands 42b are formed. There is no particular limitation as to the method for forming the conductive posts 44, but an electrolytic plating method is preferably used. According to one example, the conductive posts 44 may be formed by forming a resist mask on the insulating films 53, 54, then forming through-holes at locations corresponding to the lands 42b in order to expose the lands 42b, and then subjecting the exposed lands 42b to electrolytic plating.

Next, as shown in FIG. 9, the semiconductor chip 20 is flip-chip mounted on the second surface 33 of the insulating substrate 31 in such a way that the connection pads 42a and the bump electrodes 22 are connected. However, there is no need to form the bump electrodes 22 on the semiconductor chip 20 if projections are provided on the connection pads 42a. After the semiconductor chip 20 has been mounted, the underfill material 62 is supplied to the gap between the main surface of the semiconductor chip 20 and the insulating film 54 in order to seal said gap. It should be noted that a non-conductive film (NCF) or a non-conductive paste (NCP) may equally be used instead of the underfill material 62.

Next, as shown in FIG. 10, the semiconductor chip 10 is flip-chip mounted on the first surface 32 of the insulating substrate 31 in such a way that the connection pads 41a and the bump electrodes 12 are connected. However, there is no need to form the bump electrodes 12 on the semiconductor chip 10 if projections are provided on the connection pads 41a. After the semiconductor chip 10 has been mounted, the underfill material 61 is supplied to the gap between the main surface of the semiconductor chip 10 and the insulating film 52 in order to seal said gap. It should be noted that an NCF or an NCP may equally be used instead of the underfill material 61.

FIG. 15(a)-(c) are diagrams to illustrate the method for flip-chip mounting the semiconductor chip 10 on the first surface 32 of the insulating substrate 31.

First of all, as shown in FIG. 15(a), the insulating substrate 31 on which the semiconductor chip 20 has been mounted is placed on a stage 90. The stage 90 is provided with cavities 91, 92 for preventing interference with the semiconductor chip 20 and the conductive posts 44. Next, as shown in FIG. 15(b), the semiconductor chip 10 is picked up from the rear surface side by means of a bonding tool 93, and the bump electrodes 12 on the semiconductor chip 10 are positioned with respect to the connection pads 41a on the insulating substrate 31. The bonding tool 93 is provided with a suction-attachment nozzle 94 for suction-attaching the semiconductor chip 10, and as a result the semiconductor chip 10 can be held from the rear surface side. According to this example, an NCF (61) is applied to a surface of the semiconductor chip 10 at this point in time.

As shown in FIG. 15(c), the bonding tool 93 is then lowered so that the bump electrodes 12 on the semiconductor chip 10 come into contact with the connection pads 41a, and a load and ultrasound are applied in this state in order to bond the bump electrodes 12 and the connection pads 41a. In this process, the load applied to the wiring board 30 is concentrated at locations corresponding to the bump electrodes 12 on the semiconductor chip 10. However, in this mode of embodiment the locations where the load is concentrated, i.e. the rear surface at locations corresponding to the bump electrodes 12, is supported by means of the stage 90 so the wiring board 30 does not deform as a result of the load being applied and the semiconductor chip 20 on the rear surface is not damaged. This is because the planar shape of the semiconductor chip 10, 20 is rectangular, and the bump electrodes 12, 22 are disposed along the short sides thereof while the mounting directions of the semiconductor chip 10 and the semiconductor chip 20 are offset from each other by 90°. As a result, the semiconductor chip 10 can be mounted under the correct conditions so it is possible to improve the reliability of the semiconductor device 100.

Next, as shown in FIG. 11, both surfaces of the wiring board 30 are sealed by means of the sealing resins 71, 72 in such a way that the semiconductor chips 10, 20 and the conductive posts 44 are embedded. The sealing resins 71, 72 may be formed at the same time. As shown in FIG. 12, the surface of the sealing resin 72 is then ground until tip ends 44a of the conductive posts 44 are exposed. As a result, the ends of the conductive posts 44 and the surface of the sealing resin 72 form the same plane. In this mode of embodiment, the height of the conductive posts 44 is set to be greater than that of the semiconductor chip 20, so the rear surface of the semiconductor chip 20 is not contaminated by grinding chips such as copper produced as a result of the sealing resin 72 being ground.

As shown in FIG. 13, the solder balls 45 are then mounted at the ends of the conductive posts 44, after which the base material 31X and the sealing resins 71, 72 are cut along the dicing lines D in order to form individual units, and semiconductor devices 100 according to this mode of embodiment are completed as a result, as shown in FIG. 14. It should be noted that it is possible to prevent connection defects such as oxidation of the tip ends 44a of the conductive posts 44 if the solder balls 45 are mounted immediately after the conductive posts 44 have been exposed by grinding of the sealing resin 72.

The sealing resin 72 is thus ground until the tip ends 44a of the conductive posts 44 are exposed in the steps for manufacturing the semiconductor device 100 according to this mode of embodiment, so it is possible to reduce the overall thickness. Moreover, the semiconductor chips 10, 20 having the bump electrodes 12, 22 provided along the short sides thereof are mounted at an angle of 90° with respect to each other, so there is no deformation etc. of the wiring board 30 and it is possible to mount the semiconductor chips 10, 20 under the correct conditions.

It should be noted that the steps for manufacturing the semiconductor device 100 are not limited to the sequence described above, and the order of some of the steps may be changed. For example, after the steps shown in FIG. 8 and FIG. 9, the sealing resin 72 may be formed beforehand, as shown in FIG. 16, after which the semiconductor chip 10 may be mounted, as shown in FIG. 17. After this, the structure shown in FIG. 11 may be obtained by forming the sealing resin 71 to cover the semiconductor chip 10. According to this method, the sealing resins 71, 72 are formed in separate steps so it is possible to select different materials therefor. For example, the conductive posts 44 are present on the second surface 33 of the wiring board 30, so if the sealing resins 71, 72 are made of the same material, the sealing resin 71 is subject to more cure shrinkage than the sealing resin 72 and warping of the wiring board 30 may occur. In order to take account of this, it is possible to restrict warping of the wiring board 30 that accompanies cure shrinkage by selecting, as the material of the sealing resin 72, a material having a greater linear expansion coefficient than the material of the sealing resin 71.

A second mode of embodiment of the present invention will be described next.

FIG. 18 is a view in cross section showing the configuration of a semiconductor device 200 according to a second mode of embodiment of the present invention.

As shown in FIG. 18, the semiconductor device 200 according to this mode of embodiment differs from the semiconductor device 100 according to the first mode of embodiment in that a rear surface 10a of the semiconductor chip 10 is exposed from the sealing resin 71. The semiconductor device 200 according to this mode of embodiment is otherwise the same as the semiconductor device 100 according to the first mode of embodiment so elements which are the same bear the same reference symbols and a duplicate description will not be given.

The semiconductor device 200 according to this mode of embodiment makes it possible to achieve the same advantages as those of the semiconductor device 100 according to the first mode of embodiment and it is also possible to reduce the overall thickness. Furthermore, the sealing resin 71 which readily undergoes cure shrinkage is thinner than the sealing resin 72, so it is also possible to prevent warping of the wiring board 30 caused by a difference in cure shrinkage.

The semiconductor device 200 according to this mode of embodiment may be manufactured by grinding the surface of the sealing resin 71 until the rear surface 10a of the semiconductor chip 10 is exposed, after the step shown in FIG. 11. The conductive posts are not embedded in the sealing resin 71 so grinding chips such as copper are not generated when the surface of the sealing resin 71 is ground. The rear surface 10a of the semiconductor chip 10 is therefore not contaminated by grinding chips such as copper.

Preferred modes of embodiment of the present invention have been described above, but the present invention is not limited to these modes of embodiment and various modifications may be made within a scope that does not depart from the essential point of the present invention, and it goes without saying that any such modifications are also included in the scope of the present invention.

For example, in the first and second modes of embodiment, a wiring board 30 comprising a rigid insulating substrate 31 is used, but it is equally possible to use a flexible insulating substrate comprising polyimide or the like, instead of a rigid insulating substrate. In addition, the present invention may also be applied to a semiconductor device having a redistribution layer (RDL) structure which does not employ an insulating substrate.

Furthermore, in the manufacturing steps shown in FIG. 8-FIG. 14, the wiring board 30 on which the conductive posts 44 are formed is covered by the sealing resin 72, but the conductive posts 44 may equally be formed by covering the wiring board 30 on which the conductive posts are not formed by means of the sealing resin 72, then forming through-holes in the sealing resin 72 using laser irradiation or the like, and then introducing a conductor such as solder into the through-holes.

### KEY TO SYMBOLS

10, 20 . . . Semiconductor chip

10a . . . Rear surface of semiconductor chip

11, 21 . . . Pad electrode

12, 22 . . . Bump electrode

13, 23 . . . Solder layer

30 . . . Wiring board

31 . . . Insulating substrate

31X . . . Base material

32 . . . First surface

33 . . . Second surface

41, 42 . . . Wiring pattern

41a, 42a . . . Connection pad

42b . . . Land

43 . . . Through-hole conductor

44 . . . Conductive post

44a . . . Tip end of conductive post

45 . . . Solder hole

51-54 . . . Insulating film

51a, 53a . . . Opening

61, 62 . . . Underfill material

71, 72 . . . Sealing resin

80 . . . Package

81, 87 . . . Land

82 . . . Wiring board

83 . . . Solder hole

84 . . . Semiconductor chip

84a . . . Bump electrode

85 . . . Connection pad

86 . . . Through-hole conductor

88 . . . Underfill material

89 . . . Insulating film

90 . . . Stage

91, 92 . . . Cavity

93 . . . Bonding tool

94 . . . Suction-attachment nozzle

100, 200 . . . Semiconductor device

L11-L14, L21-L24, L31-L34 . . . Side (end)

1. A semiconductor device comprising:
a wiring board having a plurality of first connection pads formed on a first surface, a plurality of second connection pads formed on a second surface, and a plurality of lands which are disposed on the second surface and are electrically connected to the first or second connection pads;
a first semiconductor chip having a first surface defined by opposing first and second ends and opposing third and fourth ends, and a plurality of first bump electrodes which are disposed along the first and second ends on the first surface, said first semiconductor chip being mounted on the first surface of the wiring board in such a way that the plurality of first bump electrodes are connected to the plurality of first connection pads;
a first sealing resin which is formed on the first surface of the wiring board in such a way as to cover the first semiconductor chip;
a second semiconductor chip having a first surface defined by opposing first and second ends and opposing third and fourth ends, and a plurality of second bump electrodes which are disposed along the first and second ends on the first surface, said second semiconductor chip being mounted on the second surface of the wiring board in such a way that the plurality of second bump electrodes are connected to the plurality of second connection pads and in such a way that the first and second ends of the second semiconductor chip are disposed parallel to the third and fourth ends of the first semiconductor chip;
a second sealing resin which is formed on the second surface of the wiring board in such a way as to cover the second semiconductor chip;
a plurality of conductive posts which are provided running through the second sealing resin and are connected at a first end to each of the plurality of corresponding lands while a second end thereof is exposed from the second sealing resin; and
a plurality of solder balls which are mounted at the second end of the plurality of conductive posts.

2. The semiconductor device as claimed in claim 1, wherein:
the first surface of the first semiconductor chip has a rectangular shape in which the first and second ends constitute the short sides and the third and fourth ends constitute the long sides; and
the first surface of the second semiconductor chip has a rectangular shape in which the first and second ends constitute the short sides and the third and fourth ends constitute the long sides.

3. The semiconductor device as claimed in claim 1, wherein the plurality of lands are disposed at the peripheral region of the second surface of the wiring board in such a way as to surround the plurality of second connection pads.

4. The semiconductor device as claimed in claim 1, wherein the first and second semiconductor chips have the same configuration.

5. The semiconductor device as claimed in claim 1, wherein the second end of the plurality of conductive posts and the surface of the second sealing resin form the same plane.

6. The semiconductor device as claimed in claim 1, wherein the wiring board further comprises:
a plurality of first and second wiring patterns and an insulating film that covers part of the plurality of first and second wiring patterns;
the plurality of first connection pads comprise a portion in the plurality of first wiring patterns which is not covered by the insulating film; and
the plurality of second connection pads comprise a portion in the plurality of second wiring patterns which is not covered by the insulating film.

7. The semiconductor device as claimed in claim 6, wherein:
the insulating film includes first and second insulating films that cover part of the plurality of first wiring patterns;
the first insulating film is disposed between the first surface of the wiring board and the first sealing resin;
the second insulating film is disposed between the first surface of the wiring board and the first surface of the first semiconductor chip; and
the second insulating film is thinner than the first insulating film.

8. The semiconductor device as claimed in claim 6, wherein:
the insulating film includes third and fourth insulating films that cover part of the plurality of second wiring patterns;
the third insulating film is disposed between the second surface of the wiring board and the second sealing resin;
the fourth insulating film is disposed between the second surface of the wiring board and the first surface of the second semiconductor chip; and
the fourth insulating film is thinner than the third insulating film.

9. The semiconductor device as claimed in claim 1, wherein the rear surface of the first semiconductor chip positioned on the opposite side to the first surface is exposed without being covered by the first sealing resin.

10. The semiconductor device as claimed in claim 1, wherein the first sealing resin and the second sealing resin comprise different materials.

11. The semiconductor device as claimed in claim 10, wherein the first sealing resin and the second sealing resin have different linear expansion coefficients.

12. A method for manufacturing a semiconductor device, comprising:
forming a plurality of first connection pads on a first surface of a wiring board, and forming a plurality of second connection pads, a plurality of lands which are electrically connected to the first or second connection pads, and a plurality of conductive posts which are connected at a first end to each of the corresponding plurality of lands, on a second surface of the wiring board;
mounting a first semiconductor chip having a first surface defined by opposing first and second ends and opposing third and fourth ends, and a plurality of first bump electrodes disposed along the first and second ends of the first surface on the first surface of the wiring board in such a way that the plurality of first bump electrodes are connected to the plurality of first connection pads;
mounting a second semiconductor chip having a first surface defined by opposing first and second ends and opposing third and fourth ends, and a plurality of second bump electrodes disposed along the first and second ends of the first surface on the second surface of the wiring board in such a way that the plurality of second bump electrodes are connected to the plurality of second connection pads and in such a way that the first and second ends of the second semiconductor chip are disposed parallel to the third and fourth ends of the first semiconductor chip;
forming first and second sealing resins on the first and second surfaces, respectively, of the wiring board in such a way as to cover the first and second semiconductor chips;
grinding the second sealing resin in such a way that a second end of the plurality of conductive posts is exposed; and
mounting a plurality of solder balls at the second end of the plurality of conductive posts.

13. The method for manufacturing a semiconductor device as claimed in claim 12, wherein the first and second sealing resins are formed at the same time.

14. The method for manufacturing a semiconductor device as claimed in claim 12, wherein the second sealing resin covering the second semiconductor chip is formed, after which the first semiconductor chip is mounted on the first surface of the wiring board.

15. The method for manufacturing a semiconductor device as claimed in claim 12, comprising grinding the first sealing resin in such a way that the rear surface of the first semiconductor chip is exposed.
